(19) United States
(12) Patent Application Publication
(10) Pub. No.: US 2006/0005384 A1
(43) Pub. Date: Jan. 12, 2006

(54) Manufacturing method of a multi-layer circuit board with an embedded passive component

(75) Inventors: Ching-Fu Hung, Kaohsiung (TW); Yung-Hui Wang, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/174,534

(22) Filed: Jul. 6, 2005

(30) Foreign Application Priority Data
Jul. 6, 2004 (TW) 93120229

(51) Int. Cl. H01L 21/44

(52) U.S. Cl. 29/832; 438/106; 29/830; 29/831

(57) ABSTRACT

A manufacturing method of a multi-layer circuit board with an embedded passive component includes: providing a conductive layer which has a first surface and a second surface; forming a metal paste on the first surface to form metal joints; using a sintering process to connect a passive element to the corresponding metal joints; stacking a core substrate and an organic isolated layer on the first surface of the conductive layer; and forming electrical pattern connecting to the passive element on the second surface of the conductive layer.

This application claims the benefit of Taiwan application Serial No. 93120229, filed Jul. 6, 2004, the subject matter of which is incorporated herein by reference.

### BACKGROUND OF THE INVENTION

1. Field of the Invention

The invention relates in general to a manufacturing method of a multi-layer circuit board, and more particularly to a manufacturing method of a multi-layer circuit board with an embedded passive component.

2. Description of the Related Art

The object of creating a larger space within a substrate area with limited space and enhancing the multi-functions of the module is normally achieved by reducing or embedding a passive component so that more space can be used for the installation of active components. And, the multi-layer circuit board with a passive component is thus invented and provided. The above passive component can be components such as a resistor, capacitor, inductance and voltage controlled quartz oscillator and so on.

Many methods can be used to integrate several film passive components in a multi-layer circuit board. In terms of the manufacturing process of multi-layer circuit board, the key factor lies in the ability of embedding the thick-film or thin film passive component of the kind in the circuit board during manufacturing process. The key factor is how to maintain the electrical precision of the thin film passive component and reduce the variation with the original design after the thin film passive component is integrated into the multi-layer circuit board and is exemplified in Taiwanese Patent Publication No. 518616 “Manufacturing Method of a Multi-layer Circuit Board with a Passive Component” disclosed on Jan. 21, 2003. Referring to FIG. 1A and FIG. 1B, a multi-layer circuit board embedded with a passive component includes a circuit thin plate 1 whose surface has a patterned circuit layer 2, a conductive foil 3, a resistor film 5, a passivation layer 7, and a prepreg material 9. The resistor film 5 is deposited on a slightly rough region on an even surface of the conductive foil 3 to have a better adhesion, and can be appropriately heated to become solidification. The slightly rough region can be defined according to photoresist, lithography, etching, polishing, or other methods. The passivation layer 7 covers up the resistor film 5. The prepreg material 9 is located between the conductive foil 3 and the circuit thin plate 1. The circuit thin plate 1, conductive foil 3, and the prepreg material 9 are stacked together according to a hot-pressing step.

However, the above methods must take into account the manufacturing process ability of the resistor or capacitor. For example, the printing area of the resistor must be carefully controlled, preventing the printed resistor from varying with the designed value and causing bias to electrical precision. Therefore, the entire manufacturing process would become more complicated.

In the fields of close-to-mature technology, how to maintain electrical precision and at the same time simplify the manufacturing process for the current manufacturing process to better fit the needs of next generation products has become an urgent issue to be resolved.

### SUMMARY OF THE INVENTION

With regards to the above issues, it is therefore a main object of the invention to provide a manufacturing method of a multi-layer circuit board with an embedded passive component, and more particularly a manufacturing method of a multi-layer circuit board with an embedded passive component which can simplify manufacturing process and enhance electrical precision.

Another object of the invention is to provide a manufacturing method of a multi-layer circuit board with an embedded passive component without considering the manufacturing process ability of resistor or capacitor as well as the variation between the formed components and their designed values.

A further object of the invention is to provide a manufacturing method of a multi-layer circuit board with an embedded passive component such as resistor, capacitor, or inductance and so on.

In order to achieve the above objects, a manufacturing method of a multi-layer circuit board with an embedded passive component is provided. The method includes: providing a conductive layer which has a first surface and a second surface; forming a metal paste on the first surface to form metal joints; using a sintering process to connect a passive element to the corresponding metal joints; stacking a core substrate and an organic isolated layer on the first surface of the conductive layer; and forming electrical pattern connecting to the passive element on the second surface of the conductive layer.

Besides, at least a through-hole via can be formed on the core substrate for electrically connecting the conducting circuit to the conductive foils of the top and the bottom surface of the core substrate.

Besides, through the blind via formed on the insulation layer, the core substrate with surface circuit can electrically connect the circuit pattern disposed on the conductive foil to the conducting-circuit on the surface of the core substrate to form a multi-layer circuit board.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A to FIG. 1B (PriorArt) shows a manufacturing process of a conventional multi-layer circuit board embedded with a passive component;

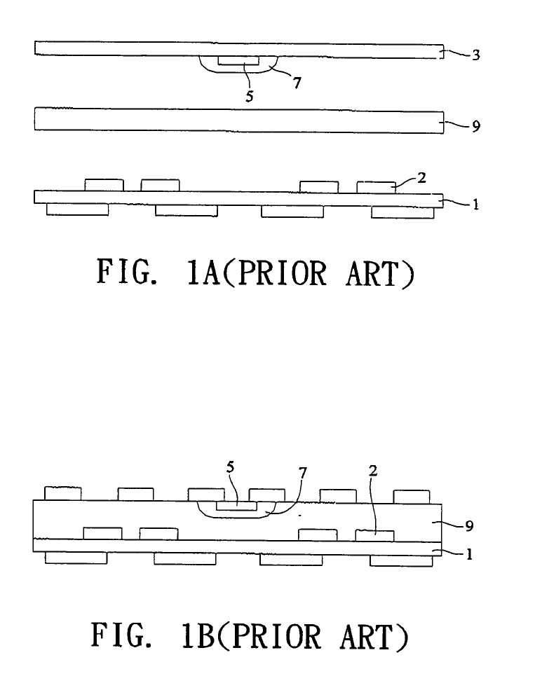

FIG. 2A to FIG. 2D shows a manufacturing process of multi-layer circuit board with an embedded passive component according to a preferred embodiment of the invention;

FIG. 3A and FIG. 3B shows an embodiment showing the circuit pattern formed on the surface of a laminated multi-layer circuit board; and

FIG. 4A and FIG. 4B shows another embodiment showing the circuit pattern formed on the surface of a laminated multi-layer circuit board.

### DETAILED DESCRIPTION OF THE INVENTION

It is noteworthy that the following drawings are not formulated according to actual scale, but are merely formulated for elaboration. That is, the actual scales and features in various layers of the multi-layer circuit board are not fully reflected.

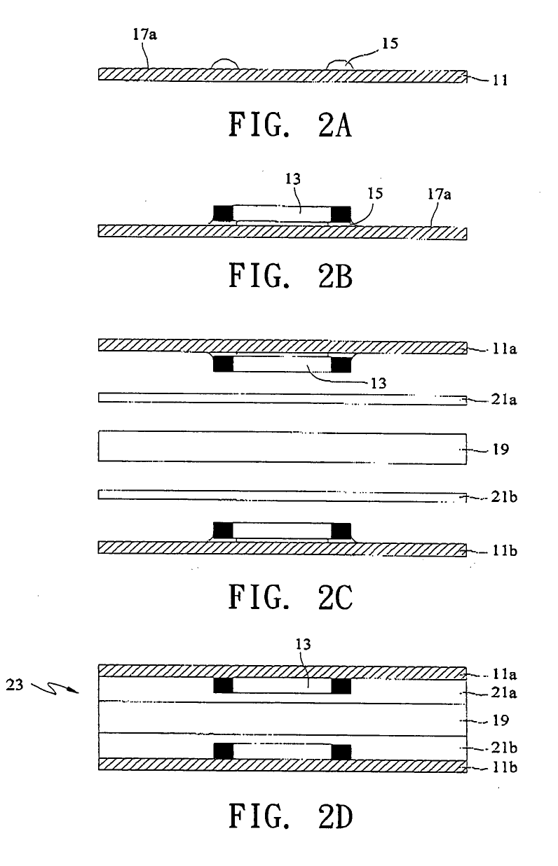

Referring to FIG. 2A to FIG. 2D, cross-sectional views of the manufacturing process of multi-layer circuit board with an embedded passive component according to a preferred embodiment of the invention are shown.

As shown in FIG. 2A, at first, a conductive foil 11 is provided. A metal paste is formed through screen printing to form a metal contact 15 of a passive component 13 (shown in FIG. 2B) on the first surface 17a of the conductive foil 11. The conductive foil 11 is made of copper, silver, aluminum, palladium or silver palladium, and is preferably made of a copper foil. The metal paste can be a copper paste, wherein the copper paste can include aluminum oxide and copper powers, or include copper oxide and glass.

As shown in FIG. 2B, the passive component 13 is formed on the corresponding metal contact 15 disposed on the first surface 17a of the conductive foil 11, and is connected to the corresponding metal contact 15 by using sintering process. The sintering temperature during the sintering process, despite may vary with the additives of the copper paste, is preferably not higher than 700 degrees centigrade. For example, the temperature may be 600 degrees centigrade. Besides, the above passive component 13 can be a capacitor, a resistor, or an inductance:

Referring to FIG. 2C, a core substrate 19, two organic insulation layers (21a, 21b), a conductive foil 11a including a passive component 13, and a conductive foil or a conductive foil 11b which also includes a passive component 13 are shown.

The first organic insulation layer (21a), the first conductive foil (11a) and one side of the core substrate 19 are stacked together, and so are the second organic insulation layer (21b), the second conductive foil (11b) and another side of the core substrate 19. The organic insulation layers (21a, 21b) are located between the core substrate 19 and the conductive foils. The first surface of the conductive foil (11a, 11b) on which the passive component 13 is disposed contacts the organic insulation layer.

The organic insulation layer (21a, 21b) can be made of prepreg material or liquid resin pasted on the surface of the core substrate 19. The core substrate 19 can be a metal circuit with patterns on double surfaces or a simple core substrate without any patterns. The core substrate 19 can be a double-layer circuit board or a multi-layer circuit board. The core substrate 19 can be made of insulated organic material or ceramic material, such as epoxy resin, polyimide, dimaleatepolyimide resin, or other fiberglass composites such as a conventional FR-4 substrate. The FR-4 substrate can be composed of epoxy resin, a fiberglass cloth and an electroplated copper foil for instance. The core substrate 19 is not limited to be composed of a single organic material. The core substrate 19 can be composed of various insulation layers as well. During the above stacking procedure, which can be achieved by hot-pressing step, alignment precision is essential and must be under good controlled.

As shown in FIG. 2D, the layers of the multi-layer circuit board 23 laminated through stacking procedure, from top to down, include the first conductive foil 11a with the passive component 13, the first organic insulation layer 21a, the core substrate 19, the second organic insulation layer 21b, the second conductive foil 11b or the second conductive foil 11b with the passive component 13.

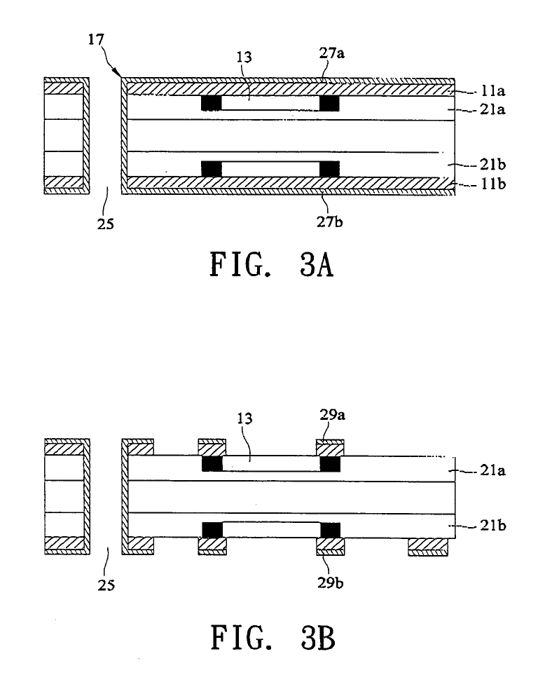

Referring to FIG. 3A and FIG. 3B, an embodiment showing the circuit pattern formed on the surface of a laminated multi-layer circuit board is shown.

As shown in FIG. 3A, at least a through-hole via 25 is formed by penetrating the first conductive foil 11a and the second conductive foil 11b, so that the circuits formed on the first conductive foil 11a and the second conductive foil 11b can be electrically connected via the through-hole vias 25. Next, a metal layer 27 is formed on the inner wall of the vias to enable electrical connection therethrough. The metal layers (27a, 27b) are respectively formed on the surface of the first conductive foil 11a and the surface of the second conductive foil 11b to enable patterning the conductive foil. The metal layer 27 may include copper. The formation of the metal layer 27, for example the formation method of a copper metal layer, can be achieved through chemical vapor deposition such as physical vapor deposition (PVD), chemical vapor deposition (CVD), electroplated copper, non-plated copper, sputtering, evaporation, arc vapor deposition, ion beam sputtering, laser ablation deposition, plasma enhanced chemical vapor deposition (PECVD) or organic metal. It is preferred to use non-plating method first and the plating method comes second to form a metal layer.

As shown in FIG. 3B, the metal layers (27a, 27b) on the top and the bottom surfaces are respectively patterned to form the electrical patterns (29a, 29b). The above method of patterning the metal layers (27a, 27b) on the top and the bottom surfaces respectively to form the electrical patterns (29a, 29b) can be achieved through the conventional manufacturing process of plating the through-hole via such as the subtractive method, which may use the panel method. According to FIG. 3B, the electrical pattern is respectively formed on the top and the bottom conductive foils. However, in the practical application, the conductive foils can be patterned. Besides, the core substrate 19 of the laminated multi-layer circuit board has electrical patterns formed on both the top surface and the bottom surface or on either of the top surface and bottom surface. This can alternatively be achieved by forming an external electrical pattern electrically connected to the electrical pattern of the core substrate on the outer surface.

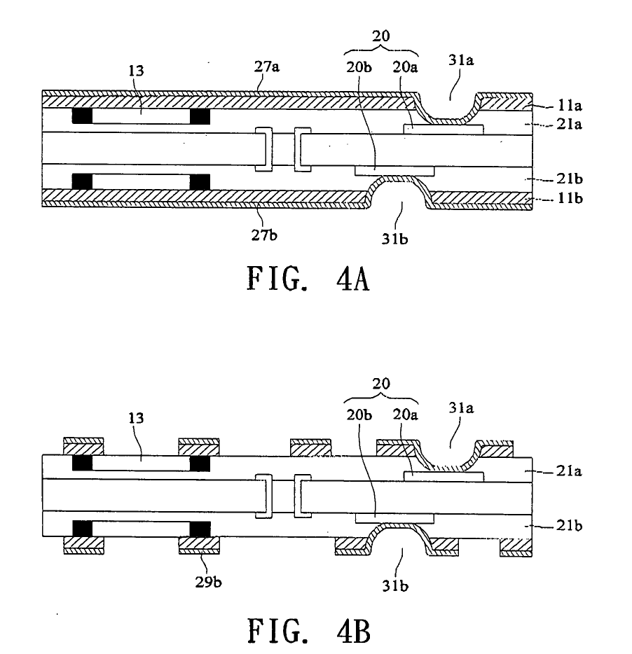

Referring to FIG. 4A and FIG. 4B, another embodiment showing the circuit pattern formed on the surface of a laminated multi-layer circuit board is shown.

As shown in FIG. 4A, at least a pair of blind vias (31a, 31b) are formed by the first conductive foil 11a, the first organic insulation layer 21a, the second conductive foil 11b and the second organic insulation layer 21b which connect the top surface to the bottom surfaces, so that the circuits 20 of the core substrate 19 respectively covered by the organic insulation layer (21a, 21b) are exposed. When a circuit is to be formed on the conductive foil, the circuit can be electrically connected to the circuit 20 of the core substrate 19 covered by organic insulation layer (21a, 21b) via the blind vias (31a, 31b). Next, a first metal layer 27a and a second metal layer 27b are respectively formed on the top surface and the bottom surface of the multi-layer circuit board 23. The first metal layer 27a covers up the first conductive foil 11a and the inner wall of the blind via 31a so as to be connected to the circuit 20a disposed on the top surface of the core substrate 19. The second metal layer 27b covers up the second conductive foil 11b and the inner wall of the blind via 31b disposed on the bottom surface so as to be connected to the circuit 20b disposed on the bottom surface of the core substrate 19. The first metal layer or the second metal layer may include copper. The formation of the metal layer, for example the formation method of a copper metal layer, can be achieved through chemical vapor deposition such as physical vapor deposition (PVD), chemical vapor deposition (CVD), electroplated copper, non-plated copper, sputtering, evaporation, arc vapor deposition, ion beam sputtering, laser ablation deposition, plasma enhanced chemical vapor deposition (PECVD) or organic metal. It is preferred to use non-plating method first and the plating method comes second to form a metal layer.

As shown in FIG. 4B, the metal layers (27a, 27b) on the top and the bottom surfaces are respectively patterned to form the electrical patterns (29a, 29b) electrically connected the circuit (20a, 20b) disposed on the top and the bottom surfaces of the core substrate 19. In FIG. 4B, the electrical pattern is respectively formed on the top and the bottom surfaces of the core substrate. However, in practical application, the core substrate can have the electrical pattern on one surface only. Despite electrical pattern is formed on the top and the bottom conductive foils in FIG. 4B, in the practical application, the electrical pattern can be formed on one of the conductive foils.

According to the manufacturing method of a multi-layer circuit board with an embedded passive component of the invention disclosed above, the metal contacts of a passive component are formed on the conductive foil through screen printing, and the passive component is connected to the metal contacts through sintering process. Therefore, there is no need to consider the printing size of the passive component, largely reducing the complexity in the manufacturing process of forming the passive component, so that the objects of simplifying the manufacturing process and enhancing electrical precision can be achieved. Besides, at least a through-hole via can be formed on the core substrate, so that the conducting circuit disposed on the top surface of the conductive foil can be electrically connected to the conducting circuit disposed on the bottom surface of the core substrate to form a multi-layer circuit board.

Moreover, the core substrate with surface circuit, via the blind via formed on, the insulation layer, can electrically connect the circuit pattern disposed on the conductive foil to the conducting circuit disposed on the surface of the core substrate to form a multi-layer circuit board. The conductive foil, according to build-up technology, can create an insulation layer on the conductive foil to form at least a circuit layer. The built-up circuit layer, via the blind via disposed on the insulation layer of the conductive foil, can be electrically connected to the conducting circuit disposed on the surface of the conductive foil.

The multi-layer circuit board may be applied to a flip chip semiconductor package substrate or an ordinary wire bonding semiconductor package substrate, so that the manufacturing process is simplified and that the manufacturing costs are effectively reduced. Therefore, the manufacturing method of a multi-layer circuit board with an embedded passive component according to the invention provides the user the manufacturing method of a multi-layer circuit board which can be applied to various manufacturing processes without having to consider the ability of the manufacturing process of the resistor or the capacitor as well as the difference between the original design and the manufactured product. The method according to the invention effectively simplifies the manufacturing process and the manufacturing costs as well.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of a multi-layer circuit board with an embedded passive component, comprising:
providing a conductive foil, wherein the conductive foil has a first surface and a second surface;
forming a metal paste on the first surface to form a metal contact;
connecting a passive component to the corresponding metal contact by using a sintering process;
stacking a core substrate and an organic insulation layer on the first surface of the conductive foil, wherein the organic insulation layer is located between the conductive foil and the core substrate, wherein the passive component is embedded in the organic insulation layer; and
patterning the conductive foil.

2. The manufacturing method according to claim 1, wherein the conductive foil is a copper foil.

3. The manufacturing method according to claim 1, wherein the metal paste is a copper paste.

4. The manufacturing method according to claim 3, wherein the copper paste includes aluminum oxide and copper powers.

5. The manufacturing method according to claim 3, wherein the copper paste includes copper oxide and glass.

6. The manufacturing method according to claim 1, wherein the passive component is selected from a group consisting of a capacitor, an inductance and a resistor.

7. The manufacturing method according to claim 1, wherein the core substrate is a double-layer circuit board.

8. The manufacturing method according to claim 1, wherein the core substrate is a multi-layer circuit board.

9. The manufacturing method according to claim 1, wherein the core substrate is made of an insulating material.

10. The manufacturing method according to claim 1, wherein the organic insulation layer is made of a prepreg material.

11. The manufacturing method according to claim 1, wherein the organic insulation layer is made of epoxy resin.

12. The manufacturing method according to claim 1, wherein the stacking step includes hot-pressing.

13. The manufacturing method according to claim 1, wherein in the connecting step by using the sintering process, sintering temperature is lower than 700 degrees centigrade.

14. The manufacturing method according to claim 13, wherein in the connecting step by using sintering process, the sintering temperature is 600 degrees centigrade.

15. The manufacturing method according to claim 1, wherein the step of forming the electrical pattern comprises:
penetrating the core substrate, the organic insulation layer and the conductive foil to form a through-hole via;
forming a metal layer on the second surface of the conductive foil and an inner wall of the through-hole via; and
patterning the metal layer of the second surface.

16. The manufacturing method according to claim 15, wherein the metal layer is made of copper.

17. The manufacturing method according to claim 1, wherein the step of forming an electrical pattern comprises:
penetrating the organic insulation layer and the conductive foil to form a blind via;
forming a metal layer on the second surface of the conductive foil and the inner wall of the blind via; and
patterning the metal layer.

18. The manufacturing method according to claim 17, wherein the metal layer is made of copper.

19. The manufacturing method according to claim 17, wherein the core substrate further comprises a buried via electrically connected to the blind via.
